(19) United States
(12) Patent Application Publication
(10) Pub. No.: US 2008/0096392 A1
(43) Pub. Date: Apr. 24, 2008

(54) Ashing system

(75) Inventor: Toru Kakuda, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 11/905,716

(22) Filed: Oct. 3, 2007

(30) Foreign Application Priority Data
Oct. 4, 2006 (JP) 2006-272539

(51) Int. Cl. H01L 21/302

(52) U.S. Cl. 438/714; 156/345.51; 257/E21.214

(57) ABSTRACT

An ashing system capable of restraining etching and damage of an oxide film or a nitride film on a semiconductor substrate and ashing a resist uniformly at a very high rate is to be provided. The ashing system includes a reaction tube, a coil and a high frequency power source for inducing and maintaining a high frequency gas discharge at inside of the reaction tube, and a chamber including a susceptor for holding a semiconductor substrate a and directly connected to the reaction tube, in which only oxygen gas is introduced into the reaction tube while exhausting inside of the reaction tube and inside of the chamber, and a pressure at inside of the reaction tube and inside of the chamber in ashing falls in a range equal to or higher than 250 Pa and equal to or lower than 650 Pa.

### BACKGROUND OF THE INVENTION

1. Field of the Invention

The present invention relates to a plasma processing apparatus, particularly to an ashing system used for fabricating a semiconductor device.

2. Description of Related Art

Generally, in a step of fabricating a semiconductor device of IC, LSI or the like, a photoresist is coated on a surface of a semiconductor substrate, thereafter, a pattern drawn on a photomask is transcribed to form a resist pattern on the surface of the semiconductor substrate. Successively, there is carried out a processing of forming a small pattern by selectively etching the surface of the semiconductor substrate in accordance with the resist pattern, or selectively injecting an impurity necessary in fabricating an embedded electrode. Further, the photoresist constituted by an organic substance which becomes unnecessary after the etching step is decomposed to remove. At that occasion, there is used an ashing system (ashing apparatus) mainly using oxygen (O₂) plasma generated by bringing about a discharge in an atmosphere mainly including oxygen gas (JP-A-09-36089 (Patent Reference 1)).

There is known an ashing system used in a background art which is provided with, for example, a chamber for ashing a resist on a semiconductor substrate on a lower side of a cylindrical quartz-made reaction tube arranged with a coil on an outer side, and provided with a susceptor (semiconductor substrate holding base) for mounting to hold the semiconductor substrate at inside of the chamber and a buffle plate disposed between the chamber and an exhausting system and serving as an exhaust resistance (JP-A-2002-93783 (Patent Reference 2)). The susceptor is pertinently heated. Further, the ashing system is connected with a high frequency power source for supplying a bias power to the susceptor for attracting a plasma to the susceptor. The quartz-made reaction tube is provided with a gas introducing portion, and a gas including oxygen gas, or a mixture gas constituted by adding a fluorine species gas to oxygen gas, or a mixture gas constituted by adding hydrogen gas to oxygen gas is introduced from the gas introducing portion. The plasma is formed by bringing about a discharge in: the gas by supplying a high frequency power to the coil arranged on the outer side of the quartz-made reaction tube.

A gas including a radical or an ionized molecule generated by discharge is introduced to the chamber, thereafter, brought into contact with the semiconductor substrate mounted to the susceptor at inside of the chamber and heated by heat transfer of plasma heat and radiation heat transfer from susceptor.

The resist on the semiconductor substrate is ashed by an ashing reaction with oxygen in a radical state or an ionized state included in the gas to be carbon dioxide, water or the like and is removed from above the semiconductor substrate. At that occasion, when the resist is denatured by reactive ion etching, ion injection or the like, in order to completely ash the resist, the gas for ashing is added with several percents of a fluorine species gas or a hydrogen species gas. Further, etching and damage of the oxide film are restrained as less as possible by also restraining the high frequency power supplied to the coil.

However, even when several percents of fluorine gas is added to oxygen gas and also the high frequency power supplied to the coil is restrained as described above, an oxide film (silicon oxide film or the like) or a nitride film (silicon nitride film or the like) formed on the semiconductor substrate is etched by an activated molecule and undergoes a damage (defect) of forming a trap level of electron in the film or the like. Further, when the bias power is supplied to the susceptor, etching of the oxide film or the nitride film and the damage are further increased. The etching or the damage is practically unpreferable, and therefore, it is necessary to restrain these. Further, by supplying the bias power to the susceptor, there appear a portion at which in-film charge is deepened and a portion in which the in-film charge is not deepened, a variation is brought about in the in-film charge, as a result, a problem is posed in quality. On the other hand, a resist ashing rate is only 1.6 micrometers, also a rate of etching the silicone oxide film is 10 nanometers per minute, as a result, a low performance to a degree of narrowly fitting to practical use is constituted.

### SUMMARY OF THE INVENTION

The invention intends to resolve the problem and it is an object thereof to provide an ashing system capable of restraining etching and damage of an oxide film or a nitride film on a semiconductor substrate and capable of carrying out ashing at a very high rate.

In order to solve the above-described problem, the invention provides an ashing system including a reaction chamber, means for inducing and maintaining a high frequency gas discharge at inside of the reaction chamber, and a chamber including a semiconductor substrate holding base for holding a semiconductor substrate and directly connected to the reaction chamber, wherein only an oxygen gas is introduced into the reaction chamber while exhausting inside of the reaction chamber and inside of the chamber and a pressure at inside of the reaction chamber and inside of the chamber in ashing falls in a range equal to or higher than 250 Pa and equal to or lower than 650 Pa. Thereby, ashing can be carried out at a very high rate and a uniformity of an ashing rate can be improved.

Preferably, there is constituted the ashing system for introducing the oxygen gas into the reaction chamber by a flow rate equal to or larger than 10 liters and equal to or smaller than 16 liters per minute. Thereby, etching and damage of an oxide film or a nitride film on the semiconductor substrate can be restrained, the ashing can be carried out at a very high rate and a uniformity of the ashing rate can be improved.

Here, a volume of the oxygen gas is constituted by a volume under normal temperature, normal pressure.

Preferably, a high frequency power equal to or larger than 2500 W and equal to or smaller than 4500 W is supplied into the reaction chamber in order to induce a high frequency gas discharge. Further preferably, there is constituted the ashing apparatus for supplying the high frequency power equal to or larger than 4000 w and equal to or smaller than 4500 W. Thereby, the ashing can be carried out at a higher rate and a uniformity of the ashing rate can be improved.

According to the invention, etching and damage of an oxide film or a nitride film on the semiconductor substrate can be restrained, ashing can be carried out at the very high rate, and a uniformity of the ashing rate can be improved.

### BRIEF DESCRIPTION OF THE DRAWINGS

FIG. 1 is a sectional view showing a constitution of an ashing system according to an embodiment of the invention.

FIG. 2 is a graph showing a result of measuring a relationship among a pressure at inside of a reaction tube and at inside of a chamber and an ashing rate of a resist and a uniformity of an ashing rate according to the invention.

FIG. 3 is a graph showing a result of measuring a relationship among a gas flow rate and a rate of ashing a resist and a rate of etching an oxide film according to the invention.

FIG. 4 is a graph showing a result of measuring a relationship among an oxygen gas flow rate and a rate of ashing a resist and a uniformity of an ashing rate according to the intention.

FIG. 5 is a graph showing a result of measuring a relationship between a measuring position of a semiconductor substrate and a charge amount in an oxide film according to the invention.

FIG. 6 is a top view showing a measuring position on a horizontal face of a semiconductor substrate according to the invention.

FIG. 7 is a graph showing a result of measuring a relationship between a measuring position of a semiconductor substrate and a charge amount in an oxide film in a constitution different from that of the invention.

FIG. 8 is a graph showing a result of measuring a relationship among a high frequency power supplied to a coil and a rate of ashing a resist and a uniformity of an ashing rate according to the invention.

### DESCRIPTION OF PREFERRED EMBODIMENTS

Next, an embodiment of the invention will be explained in reference to the drawings.

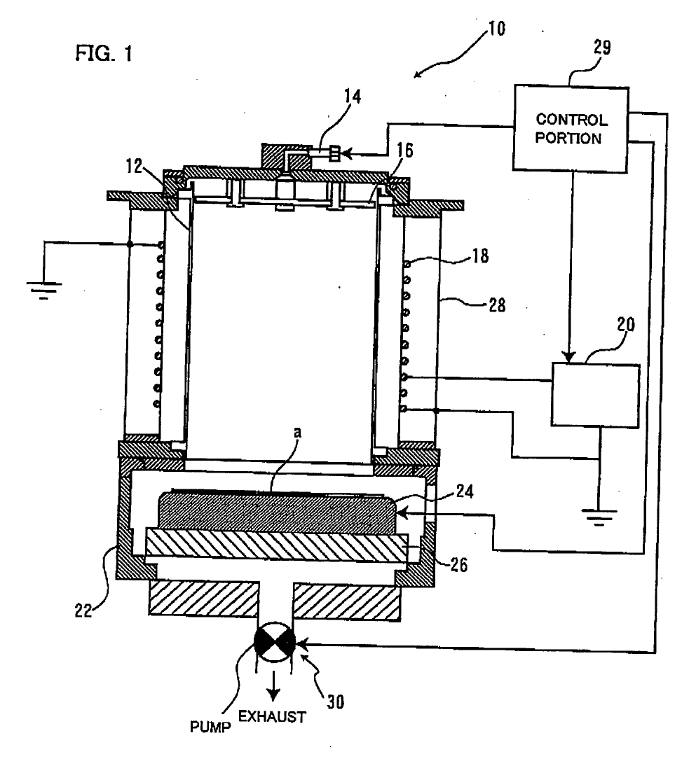

In FIG. 1, an outline of an ashing system 10 according to an embodiment of the invention will be shown.

In FIG. 1, numeral 12 designates a quartz-made reaction tube (reaction chamber) in a cylindrical shape, numeral 14 designates a gas introducing portion for introducing oxygen gas to the reaction tube 12. A gas introducing flow rate is controlled by a gas flow rate control portion of a mass controller (not illustrated) or the like. Numeral 16 designates a quartz buffle plate in a circular disk shape for making a gas introduced from the gas introducing portion 14 flow along an inner wall of the reaction tube 12. Numeral 18 designates a coil for generating a plasma by bringing about a discharge in the gas at inside of the reaction tube 12, numeral 20 designates a high frequency power source for supplying a high frequency power to the coil 18. That is, the coil 18 and the high frequency power source 20 are means for inducing and maintaining the high frequency gas discharge at inside of the reaction tube 12. Numeral 22 designates a chamber for ashing (ashing) a resist on a semiconductor substrate a. The chamber 22 is directly connected to the reaction tube 12 without a hindrance for hindering the flow of the gas. Inside of the chamber 22 is arranged with a susceptor (semiconductor substrate holding base) 24 for mounting and holding the semiconductor substrate a after the etching step, the susceptor 24 is pertinently heated by a heater provided at inside of the susceptor 24. Numeral 26 designates a buffle ring disposed between the chamber 22 and an exhaust system 30 and serving as an exhaust resistance, numeral 28 designates a shield for retaining the high frequency power at inside of the apparatus to be prevented from being leaked to outside. The exhaust system 30 is connected with a pump or the like for exhausting a processing gas by controlling the pump. Numeral 29 designates a control portion. The control portion 29 controls various constitutions of a control of a flow rate of introducing a gas introduced from the gas introducing portion 14, a control of the high frequency power source 20, a control of a temperature of the susceptor, a control of exhausting the gas and the like.

A pressure at inside of the chamber 22 is controlled by controlling the flow rate of introducing the gas and the control of exhausting the gas.

In the ashing system 10 shown in FIG. 1, only oxygen gas is introduced into the reaction tube 12 from the gas introducing portion 14. The high frequency power is supplied from the high frequency power source 20 to the coil 18, a discharge is induced in the gas of the reaction tube 12, and the plasma is formed. A gas including a radical or an ionized molecule generated by the discharge is introduced to the chamber 22 and is brought into contact with the semiconductor substrate a mounted on the heated susceptor 24 at inside of the chamber 22 and heated by heat of the plasma and radiation heat transfer from the susceptor 24.

A resist on the semiconductor substrate a is ashed (oxidized) by an ashing reaction (oxidizing reaction) with oxygen in a radical state or an ionized state included in the gas to be carbon dioxide, water or the like and is removed from above the semiconductor substrate a. At this occasion, also an oxide film (silicon oxide film or the like) or a nitride film (silicone nitride film or the like) formed on the semiconductor substrate a is etched by an activated molecule and undergoes a damage of generating a trap level of an electron at inside of the film or the like. Hence, in the ashing system 10 according to the embodiment of the invention, in order to restrain the etching and damage of the oxide film, the nitride film, the gas for ashing is not added with fluorine species gas or hydrogen species gas and only oxygen gas is used therefor.

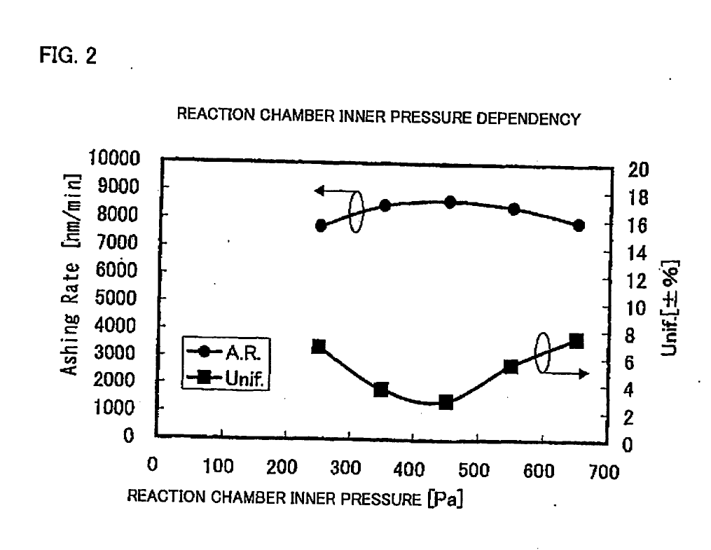

Next, Table 1 and a graph of FIG. 2 in correspondence with Table 1 show a relationship among a pressure at inside of the reaction tube 12 and at inside of the chamber 22 and a resist ashing rate and a uniformity of a resist ashing rate. At a graph of FIG. 2, a curve of black circle shows the rate of ashing the resist and a curve of black square shows the uniformity of the ashing rate. The abscissa of FIG. 2 shows the pressure at inside of the reaction tube 12 and inside of the chamber 22 in ashing. Further, in Table 1 and FIG. 2, a temperature of the semiconductor substrate is 250° C., a high frequency power of 4500 W is supplied to the coil 18, and a bias power is not supplied to the susceptor 24. Further, a flow rate of oxygen gas introduced into the reaction tube 12 is constituted by 13 liters per minute. Further, a volume of oxygen gas is a volume under normal temperature, normal pressure. In Table 1 and FIG. 2, the resist ashing rates and uniformities of the ashing rates are calculated at the pressures at inside of the reaction tube 12 and inside of the chamber 22 of 250 Pa, 350 Pa, 450 Pa, 550 Pa, 650 Pa.

TABLE 1

| | Condition | | | | Ashing | Uniformity |
|---|---|---|---|---|---|---|
| | O₂ | Pressure | RF | Temperature | rate | of ashing |
| No. | [sccm] | [Pa] | [W] | [deg. C.] | [nm/min] | rate [%] |
| 1 | 13000 | 250 | 4500 | 250 | 7727.6 | 6.7 |
| 2 | 13000 | 350 | 4500 | 250 | 8500.0 | 3.6 |
| 3 | 13000 | 450 | 4500 | 250 | 8676.2 | 2.8 |
| 4 | 13000 | 550 | 4500 | 250 | 8455.8 | 5.5 |
| 5 | 13000 | 650 | 4500 | 250 | 7927.0 | 7.5 |

That the pressure at inside of the reaction tube 12 and inside of the chamber 22 is low when the gas flow rate is constant as in the case of Table 1 and FIG. 2 signifies that a flow speed of the gas at inside of the reaction tube 12 and inside of the chamber 22 is large. Therefore, as is apparent from Table 1 and FIG. 2, when the flow speed of the gas becomes extremely large, that is, the pressure becomes extremely low, excited oxygen gas is exhausted from the chamber 22 before bringing about the ashing reaction sufficiently with the resist, and therefore, a reduction in the ashing rate is brought about.

On the contrary, that the pressure at inside of the reaction tube 12 and inside of the chamber 22 becomes high signifies that the flow rate of the gas at inside of the reaction tube 12 and inside of the chamber 22 is small, and at a certain moment, an amount of oxygen gas present at inside of the reaction tube 12 and inside of the chamber 22 is large. This signifies that an amount of a high frequency power energy necessary for excitation provided to oxygen gas per unit amount becomes small, and therefore, a rate of oxygen gas which is not sufficiently brought into an excited state is increased, and therefore, a reduction in the ashing rate is brought about.

It is regarded from Table 1 and FIG. 2 that when the uniformity of the ashing rate is also taken into consideration, it is pertinent that the pressure at inside of the reaction tube 12 and inside of the chamber 22 falls in a range equal to or higher than 250 Pa and equal to or lower than 650 Pa. When the uniformity of ashing is excessively nonuniform, at certain time, there are brought about a portion at which the resist is removed swiftly and a portion at which the resist is not removed. Although in order to remove the portion at which the resist is not removed, the portion is continued to be processed by the plasma, there is a case of machining a matrix film of the portion at which the resist has already been removed It is preferable to minimize the change of the matrix film, and therefore, it is preferable that a numerical value of the uniformity of ashing is as low as possible.

From the above-described experimental result, by making the pressure at inside of the reaction chamber and the pressure at inside of the chamber in ashing fall in the range equal to or higher than 250 Pa and equal to or lower than 650 Pa by only introducing oxygen gas, the rate of ashing the resist on the semiconductor substrate a can significantly be promoted. Further, ashing can be carried out at a high rate equal to or higher than above 8 micrometers per minute and also the uniformity of the ashing rate can be improved.

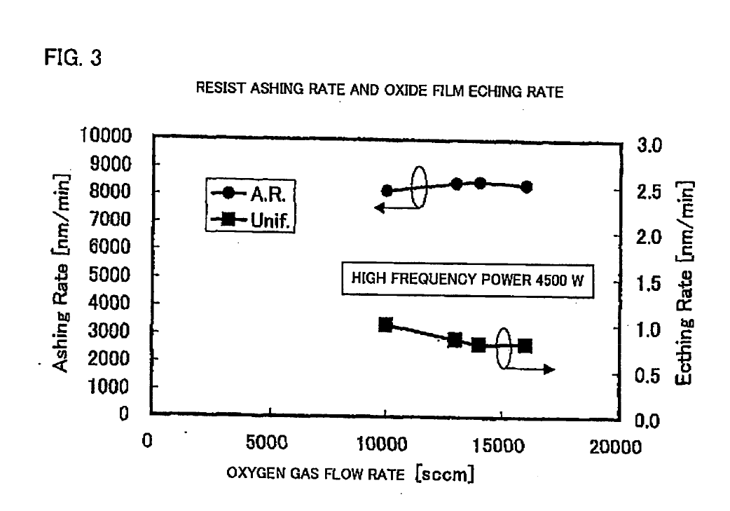

Next, Table 2 and a graph of FIG. 3 in correspondence with Table 2 show a relationship among a flow rate of oxygen gas and the resist ashing rate and a rate of etching a silicon oxide film. In the graph of FIG. 3, a curve of black circle shows the rate of ashing the resist, a curve of black square shows the rate of etching the silicon oxide film. The abscissa of FIG. 3 shows the flow rate of oxygen gas introduced to the reaction tube 12. Further, in Table 2 and FIG. 3, the temperature of the semiconductor substrate a is 250° C., the pressure at inside of the reaction tube 12 and inside of the chamber 22 is constituted by 550 Pa, the high frequency power of 4500 W is supplied from the high frequency power source 20 to the coil 1B and the bias power is not supplied to susceptor 24. Further, only oxygen gas is introduced by a flow rate equal to or larger than 10 liters (10000 sccm in FIG. 3) and equal to or smaller than 16 liters (in FIG. 3, 16000 sccm) per minute. Specifically, only oxygen gas is introduced into the reaction tube 12 by 10 liters, 13 liters, 14 liters, 16 liters per minute. Here, the volume of oxygen gas is the volume under normal temperature, normal pressure.

TABLE 2

| | Condition | | | | Ashing | Etching |
|---|---|---|---|---|---|---|
| | O₂ | Pressure | RF | Temperature | rate | rate |
| No. | [sccm] | [Pa] | [W] | [deg. C.] | [nm/min] | [nm/min] |
| 1 | 10000 | 550 | 4500 | 250 | 8165.8 | 1 |
| 2 | 13000 | 550 | 4500 | 250 | 8455.8 | 0.85 |
| 3 | 14000 | 550 | 4500 | 250 | 8508.5 | 0.8 |
| 4 | 16000 | 550 | 4500 | 250 | 8401.1 | 0.8 |

As is apparent from Table 2 and FIG. 3, the flow rate of oxygen gas introduced into the reaction tube 12 is equal to or larger than 10 liters and equal to or smaller than 16 liters per minute and the rate of ashing the resist is 8 micrometers per minute. On the other hand, the rate of etching the silicon oxide film is equal to or smaller than 1 nanometer per minute, showing that damage of the silicon oxide film can be restrained to be low, which is a performance of sufficiently resolving the problem of the background art.

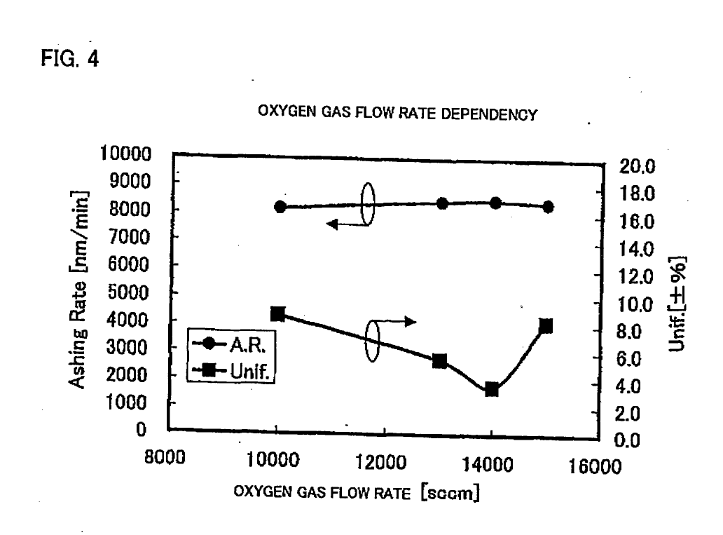

Next, Table 3 and a graph of FIG. 4 in correspondence with Table 3 show a relationship among the flow rate of oxygen gas introduced into the reaction tube 12 and the resist ashing rate and the uniformity of the ashing rate. In FIG. 4, a curve of black circle shows a rate of ashing the resist, a curve of black square shows a uniformity of the ashing rate. The abscissa of FIG. 4 shows the flow rate of oxygen gas introduced into the reaction tube 12. Further, in Table 3 and FIG. 4, the temperature of the semiconductor substrate is 250° C., the pressure at inside of the reaction tube 12 and inside of the chamber 22 is constituted by 550 Pa, the high frequency power of 4500 W is supplied to the coil 18, and the bias power is not supplied to the susceptor 24. Further, the flow rates of oxygen gas introduced into the reaction tube 12 are constituted by 10 liters, 13 liters, 14 liters, 15 liters per minute. Here, the volume of oxygen gas is the volume under normal temperature, normal pressure.

TABLE 3

| | Condition | | | | Ashing | Uniformity |
|---|---|---|---|---|---|---|
| | O₂ | Pressure | RF | Temperature | rate | of ashing |
| No. | [sccm] | [Pa] | [W] | [deg. C.] | [nm/min] | rate [%] |
| 1 | 10000 | 550 | 4500 | 250 | 8165.8 | 8.6 |
| 2 | 13000 | 550 | 4500 | 250 | 8455.8 | 5.5 |
| 3 | 14000 | 550 | 4500 | 250 | 8508.5 | 3.5 |
| 4 | 15000 | 550 | 4500 | 250 | 8401.1 | 8.2 |

That the gas flow rate is large when the pressure at inside of the reaction tube 12 and inside of the chamber 22 is constant as in the case of Table 3 and FIG. 4 signifies that the flow speed of the gas at inside of the reaction tube 12 and inside of the chamber 22 is large. When the flow speed of the gas becomes extremely large, that is, when the gas flow rate becomes extremely large, the excited oxygen gas is exhausted from inside of the chamber 22 before bringing about the ashing reaction sufficiently with the resist, and therefore, a reduction in ashing rate is brought about. Further, on the contrary, that the gas flow rate becomes small signifies that the flow speed of the gas at inside of the reaction tube 12 and inside of the chamber 22 is small, the gas is stagnated (a time period of the gas staying at inside of the reaction tube 12 and inside of the chamber 22 becomes long and a gas substitution is difficult to be brought about), and therefore, an oxygen concentration at inside of the reaction tube 12 and inside of the chamber 22 is reduced, and therefore, a reduction in the ashing rate is brought about. Therefore, it can be regarded that when the uniformity of the ashing rate is also taken into consideration, it is pertinent that the oxygen gas flow rate falls in a range equal to or larger than 10 liters and equal to or smaller than 16 liters per minute.

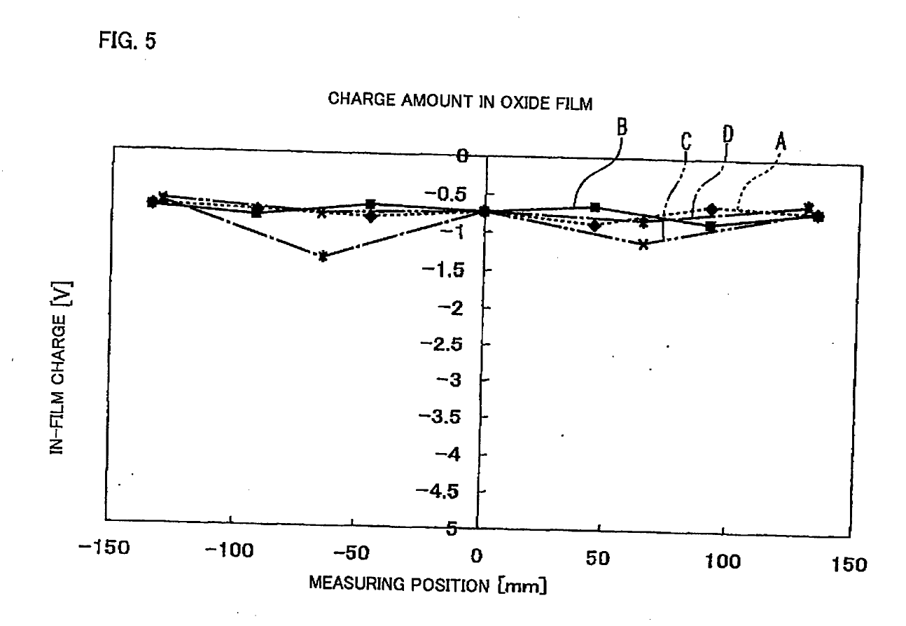

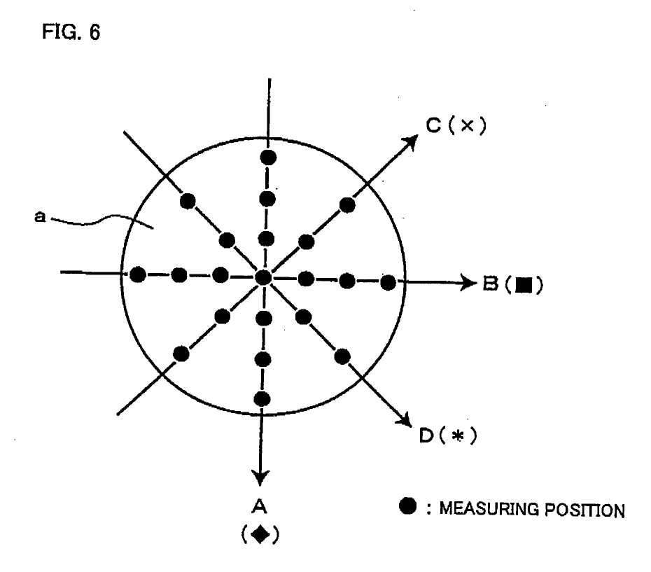

Next, Table 4 and a graph of FIG. 5 in correspondence with Table 4 show a result of measuring a charge amount after bringing an electron into an oxide film to charge up by changing a position on the semiconductor substrate a when a discharge is carried out in oxygen gas at the reaction tube 12 of the ashing system 10 according to the embodiment of the invention for the oxide film which has grown on the semiconductor substrate. Polygonal lines of A, B, C, D in FIG. 5 show a measurement result in different measuring directions on a horizontal face of the semiconductor substrate a, as shown by FIG. 6, A is measured at 7 portions (black rhomb in FIG. 5) in a vertical direction of the semiconductor substrate a in FIG. 6, B measures 7 portions (black square in FIG. 5) in a horizontal direction, C (× in FIG. 5) and D (* in FIG. 5) measure 5 portions in skewed directions. In table 4 and FIG. 5, the temperature of the semiconductor substrate a is 250° C., only oxygen gas is introduced to the reaction tube 12 by 13 liters per minute, the pressure at inside of the reaction tube 12 and inside of the chamber 22 is constituted by 550 Pa, the high frequency power of 4500 W is supplied from the high frequency power source 20 to the coil 18, and the bias power is not supplied to the susceptor 24. The abscissa of the graph of FIG. 5 shows a measurement position on the horizontal face of the semiconductor substrate a, the ordinate shows & charge amount (V) in the oxide film.

TABLE 4

| | A | B | C | D |
|---|---|---|---|---|
| −134.35 | −0.7 | −0.751 | | |
| −130 | | | −0.685 | −0.668 |
| −91.924 | −0.777 | −0.831 | | |
| −65 | | | −0.799 | −1.386 |
| −45.255 | −0.83 | −0.691 | | |
| 0 | −0.751 | −0.751 | −0.751 | −0.751 |
| 45.2548 | −0.901 | −0.656 | | |
| 65 | | | −1.139 | −0.839 |
| 91.9239 | −0.634 | −0.865 | | |
| 130 | | | −0.706 | −0.598 |
| 134.35 | −0.688 | −0.692 | | |

As is apparent from Table 4 and FIG. 5, the charge amount in the oxide film is about −1 V at any position on the horizontal face of the semiconductor substrate a.

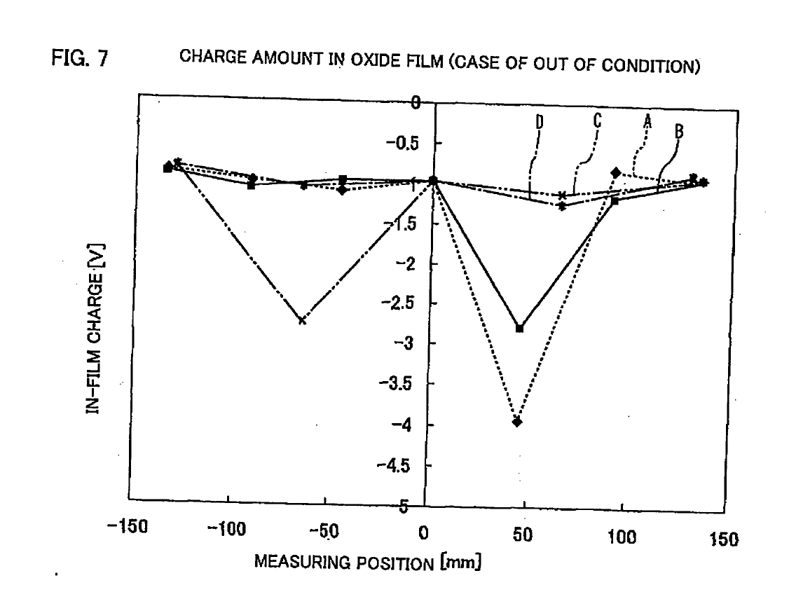

Meanwhile, Table 5 and FIG. 7 in correspondence with Table 5 show a result of measuring the charge amount in the oxide film by changing the position on the semiconductor substrate a when only the oxygen gas is introduced into the reaction tube 12 by a constitution different from the constitution of the invention. In Table 5 and FIG. 7, the temperature of the semiconductor substrate is 250° C., the pressure at inside of the reaction tube 12 and inside of the chamber 22 is 180 Pa, the high frequency power of 3500 W is supplied from the high frequency power source 20 to the coil 18, and the oxygen gas of 8 liters per minute is introduced into the reaction tube 12. Here, the volume of oxygen gas is the volume under normal temperature, normal pressure. Farther, in this case, the bias power is supplied to the susceptor 24. Polygonal lines of A, B, C, D in FIG. 7 show a result of measurement in different measuring directions on the horizontal face of the semiconductor substrate a, as shown by FIG. 6, A measures 7 portions (black rhomb in FIG. 7) in the vertical direction of the semiconductor substrate a in FIG. 6, B measures 7 portions (black square in FIG. 7) in the horizontal direction, C (× in FIG. 7) and D (* in FIG. 7) measure 5 portions in skewed directions. The abscissa of the graph of FIG. 7 shows the measuring position on the horizontal face of the semiconductor substrate a, the ordinate shows a charge amount in the oxide film.

TABLE 5

| | A | B | C | D |
|---|---|---|---|---|
| −134.35 | −0.8694 | −0.899 | | |
| −130 | | | −0.82305 | −0.83233 |
| −91.924 | −0.9818 | −1.0566 | | |
| −65 | | | −2.79274 | −1.0426 |
| −45.255 | −1.0945 | −0.9715 | | |
| 0 | −0.9625 | −0.9625 | −0.96246 | −0.96246 |
| 45.2548 | −3.9435 | −2.8068 | | |
| 65 | | | −1.11386 | −1.23145 |
| 91.9239 | −0.8198 | −1.1278 | | |
| 130 | | | −0.8624 | −0.85056 |
| 134.35 | −0.9152 | −0.9144 | | |

In this case, depending on the position on the horizontal face of the semiconductor substrate a, there appear a portion at which the in-film charge is deepened and a portion at which the in-film charge is not deepened and a variation is brought about in the in-film charge. That is, the charge amount in the oxide film is considerably changed, and it is known that damage of the oxide film is very large in comparison with the case of the constitution of the ashing system of the invention.

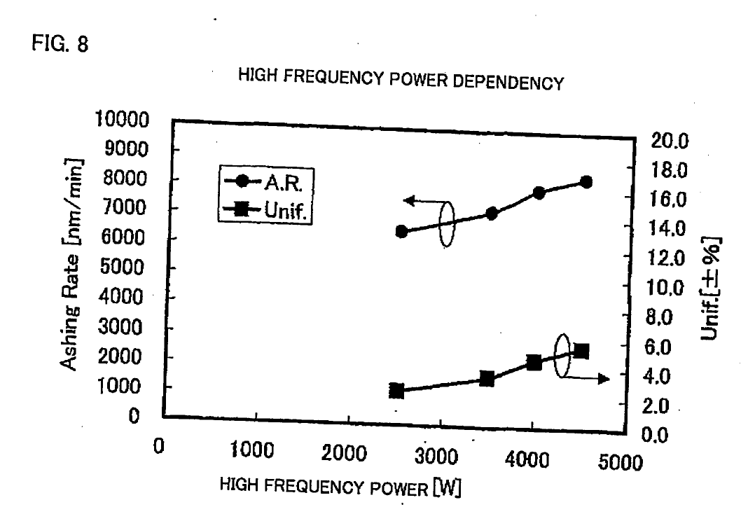

Next, Table 6 and a graph of FIG. 8 in correspondence with Table 6 show a relationship among the high frequency power supplied to the coil 18 and the rate of ashing the resist and the uniformity of the ashing rate. In a graph of FIG. 8, a curve of black circle shows the rate of ashing the resist, a curve of black square shows the uniformity of the ashing rate. Further, in Table 6 and FIG. 8, a temperature of the semiconductor substrate is 250° C., and only the oxygen gas is introduced into the reaction tube 12 by 13 liters per minute. Here, the volume of the oxygen gas is the volume under normal temperature, normal pressure. The pressure at inside of the reaction tube 12 and inside of the chamber 22 is constituted by 550 Pa, and the high frequency power is supplied from the high frequency power source 20 to the coil 18 by changing a value thereof as 2500 W, 3500 W, 4000 W, 4500 W. Further, the bias power is not supplied to the susceptor 24.

TABLE 6

| | Condition | | | | Ashing | Uniformity |
|---|---|---|---|---|---|---|
| | O₂ | Pressure | RF | Temperature | rate | of ashing |
| No. | [sccm] | [Pa] | [W] | [deg. C.] | [nm/min] | rate [%] |
| 1 | 13000 | 550 | 2500 | 250 | 6517 | 2.3 |
| 2 | 13000 | 550 | 3500 | 250 | 7253 | 3.4 |
| 3 | 13000 | 550 | 4000 | 250 | 8009 | 4.6 |
| 4 | 13000 | 550 | 4500 | 250 | 8456 | 5.5 |

As is apparent from Table 6 and FIG. 8, the larger the high frequency power supplied to the coil 18, the more increased the ashing rate. In accordance with an increase in the high frequency power, an amount of excited oxygen gas is increased, and the ashing reaction is promoted by bringing a large amount of the excited oxygen gas into contact with the resist. In order to carry out ashing at a high rate equal to or larger than 8 micrometers per minute, it is effective to make the high frequency power equal to or larger than 4000 W. In that case, also a numerical value of the uniformity of the ashing rate can be restrained to be within ±6% and also the uniformity of the ashing rate can be regarded to be excellent. Although the numerical value of the uniformity of the ashing rate is preferably larger than 6%, when the numerical value of the uniformity of the ashing rate is excessively high, there are brought about a portion at which the resist remains and a portion at which the resist is removed even by a processing of a constant time period, and there is a case in which a matrix film of the portion at which the resist has already been removed is machined by the plasma during a time period of removing the remaining resist. Therefore, it is preferable that the numerical value of the uniformity of the ashing rate is as near to 0 as possible and the invention can improve the uniformity of the ashing rate.

As described above, the invention can provide the ashing system capable of restraining etching and damage of the oxide film or the nitride film on the semiconductor substrate and capable of ashing the resist on the semiconductor substrate uniformly at a very high rate.

1. An ashing system comprising:
a reaction chamber;
means for inducing and maintaining a high frequency gas discharge at inside of the reaction chamber; and
a chamber including a semiconductor substrate holding base for holding a semiconductor substrate and directly connected to the reaction chamber;
wherein only an oxygen gas is introduced into the reaction chamber while exhausting inside of the reaction chamber and inside of the chamber and a pressure at inside of the reaction chamber and inside of the chamber in ashing falls in a range equal to or higher than 250 Pa and equal to or lower than 650 Pa.

2. The ashing system according to claim 1, wherein the oxygen gas is introduced into the reaction chamber by flow rate equal to or larger than 10 liters and equal to or smaller than 16 liters per minute.

3. An ashing system comprising:
a reaction chamber;
a gas introducing portion for supplying oxygen to the reaction chamber;
a coil for generating a plasma by discharging electricity in the oxygen introduced into the reaction chamber;
a high frequency power source for supplying a high frequency power equal to or larger than 2500 W and equal to or smaller than 4500 W to the coil; and
a susceptor for mounting a semiconductor substrate.

4. An ashing system comprising:
a reaction chamber;
means for inducing and maintaining a high frequency gas discharge at inside of the reaction chamber; and
a chamber including a semiconductor substrate holding base for holding a semiconductor substrate and directly connected to the reaction chamber;
wherein only an oxygen gas is introduced into the reaction chamber while exhausting inside of the reaction chamber and inside of the chamber and a pressure at inside of the reaction chamber and at inside of the chamber in ashing falls in a range equal to or higher than 350 Pa and equal to or lower than 550 Pa.

5. The ashing system according to claim 1, wherein the oxygen gas is introduced by 13 liters or more and 16 liters or less per minute.

6. The ashing system according to claim 1, wherein the semiconductor substrate is at 250° C. when the semiconductor substrate is processed by the plasma.

7. An ashing method comprising:
a step of mounting a substrate;
a step of making a pressure of a reaction chamber equal to or higher than 250 Pa and equal to or lower than 650 Pa;
a step of supplying oxygen to the reaction chamber;
a step of supplying a high frequency power to a coil by a high frequency power source to form the supplied oxygen into a plasma; and
a step of processing the substrate.

8. An ashing method comprising:
a step of mounting a substrate;
a step of making a pressure of a reaction chamber equal to or higher than 350 Pa and equal to or lower than 550 Pa;
a step of supplying oxygen to the reaction chamber;
a step of supplying a high frequency power to a coil by a high frequency power source to form the supplied oxygen into a plasma; and
a step of processing the substrate.

9. The ashing method according to claim 7, wherein at the step of introducing the oxygen, a flow rate equal to or larger than 10 liters and equal to or smaller than 16 liters per minute is constituted.

10. The ashing method according to claim 7, wherein the oxygen gas is introduced by 13 liters or more and 16 liters or less per minute.

11. The ashing system according to claim 2, wherein the oxygen gas is introduced by 13 liters or more and 16 liters or less per minute.

12. The ashing system according to claim 3, wherein the oxygen gas is introduced by 13 liters or more and 16 liters or less per minute.

13. The ashing system according to claim 4, wherein the oxygen gas is introduced by 13 liters or more and 16 liters or less per minute.

14. The ashing system according to claim 2, wherein the semiconductor substrate is at 250° C. when the semiconductor substrate is processed by the plasma.

15. The ashing system according to claim 3, wherein the semiconductor substrate is at 250° C. when the semiconductor substrate is processed by the plasma.

16. The ashing system according to claim 4, wherein the semiconductor substrate is at 250° C. when the semiconductor substrate is processed by the plasma.

17. The ashing system according to claim 5, wherein the semiconductor substrate is at 250° C. when the semiconductor substrate is processed by the plasma.

18. The ashing method according to claim 8, wherein at the step of introducing the oxygen, a flow rate equal to or larger than 10 liters and equal to or smaller than 16 liters per minute is constituted.

19. The ashing method according to claim 8, wherein the oxygen gas is introduced by 13 liters or more and 16 liters or less per minute.

20. The ashing method according to claim 9, wherein the oxygen gas is introduced by 13 liters or more and 16 liters or less per minute.
